(19) United States
(12) Patent Application Publication
(10) Pub. No.: US 2026/0259280 A1
(43) Pub. Date: Sep. 3, 2026

(54) METHOD AND CONTROLLER FOR AN ELECTRIC LOAD WITH SWITCH TESTING

(71) Applicant: Deere & Company, Moline, IL (US)

(72) Inventor: Christopher L. MAROHL, Fargo, ND (US)

(73) Assignee: Deere & Company, Moline, IL (US)

(21) Appl. No.: 19/538,471

(22) Filed: Feb. 12, 2026

Related U.S. Application Data
(60) Provisional application No. 63/766,195, filed on Mar. 3, 2025.

(51) Int. Cl. G01R 31/52; G01R 31/26; G01R 31/327; G01R 31/42

(52) U.S. Cl. CPC G01R 31/52; G01R 31/2621; G01R 31/3277; G01R 31/3278; G01R 31/42

(57) ABSTRACT

A method of detecting whether a deficiency is present in a system includes providing electrical energy to semiconductor switches of a controller in the controller system; measuring a direct current voltage across each of the semiconductor switches in the controller; and detecting that the deficiency is present, if the direct current voltage measured across any of the semiconductor switches is higher or lower than a threshold voltage.

### RELATED APPLICATIONS

The present application claims priority under 35 U.S.C. § 119 to U.S. Provisional Application No. 63/766,195 filed on Mar. 3, 2025, the entire contents of which are hereby incorporated by reference in its entirety.

### FIELD

Example embodiments relate to a method, and/or a controller for an electric load with switch testing to detect deficiencies in a system of, for example, motor controllers, inverters, and/or power electronics systems used in electric vehicle propulsion, industrial machinery, or other motor drive applications.

### BACKGROUND

An electric load may feature a rotor with permanent magnets and a stator, such as an interior permanent magnet (IPM) motor or an IPM synchronous motor. An inverter or motor controller, generically referenced here as a converter, may include semiconductor switches that support the provision of alternating current outputs for one or more phases of the electric load. One or more of the semiconductor switches may fail in an open state (i.e., discontinuity) or a closed state (i.e., short circuit) with respect to the output terminals of the respective semiconductor switch. The electrical load may also fail open or short.

Converter and/or electrical load failures may result in loss of propulsion, potential safety hazards, or costly warranty repairs. Further, unexpected failures of semiconductor switches or the electrical load can cause unplanned downtime, damage to motors and driven equipment, and reduced system reliability. Detection of system failures, or deficiencies, before they cause operational problems or damage is therefore highly desirable.

However, conventional converters may typically lack the ability to detect deficiencies before the controller enters operational mode where high currents and voltages may cause damage to the controller, the load or both. Instead, conventional converters typically follow a ‘power-on-and-operate’ methodology where the controller immediately transitions to operational mode upon receiving power, without performing comprehensive pre-operational diagnostics and, instead, may rely on reactive fault detection methods such as over-current protection, desaturation detection, or thermal shutdown, which only activate after a fault has already begun to cause damage. This reactive approach can result in catastrophic failures, expensive component damage, and safety hazards, particularly in high-power applications such as electric vehicle propulsion systems.

### SUMMARY

In accordance with one example embodiment, a method, a controller and a system including a controller is presented for testing said system for deficiencies. For each phase of a controller, a pair of complimentary semiconductor switches includes a high side switch and a low side switch. A direct current voltage bus provides electrical energy to the semiconductor switches. One or more measuring circuits (e.g., voltage sensor) are configured to measure the direct current voltage across each switch. A data processor determines that a deficiency (e.g., a short circuit) is present in the system if the measured direct current voltage across any switch is below a specified value when all switches are commanded open (off), or if other sequential test results indicate a deficiency (e.g., an open circuit) in one or more locations in the system. If the deficiency is present in the system, the data processor may prevent the voltage supply from applying the full operational voltage to the system to prevent damage to the load and/or the controller.

In some example embodiments, a method of detecting whether a deficiency is present in a system may include providing electrical energy to semiconductor switches of a controller in the system; measuring a direct current voltage across each of the semiconductor switches in the controller; and detecting that the deficiency is present, if the direct current voltage measured across any of the semiconductor switches is higher or lower than a threshold voltage.

In some example embodiments, the method may further include generating an alert in response to detecting the deficiency, wherein the alert includes one or more of a visual display message, an illuminated indicator, or an audible alarm.

In some example embodiments, the system may include an electrical load, the electrical load being one of an internal permanent magnet motor, a switch reluctance motor, a brake chopper resistor, or a filter network.

In some example embodiments, the method may further include inhibiting a voltage supply from providing an operational voltage level to a direct current bus of the system, in response to detecting that the deficiency is present.

In some example embodiments, the system may be coupled to a propulsion motor operating as an electrical load, and wherein inhibiting providing of the operational voltage level inhibits the propulsion motor from driving a vehicle.

In some example embodiments, the deficiency may include one or more of i) an open circuit of an activated semiconductor switch, ii) a short circuit of a deactivated one of the semiconductor switches, iii) a failure of a connection of the controller with an electrical load, or iv) a failure of the electrical load.

In some example embodiments, the providing electrical energy may include providing one or more test voltage levels to a direct current bus, the test voltage levels being equal to or less than a maximum level of an operational voltage level of the system; and measuring the direct current voltage across each of the semiconductor switches while the test voltage levels are applied to the direct current bus.

In some example embodiments, the method may further include increasing the electrical energy supplied from the one or more test voltage levels to the operational voltage level, only after determining that there are no deficiencies present in the system; or that the deficiencies detected will not adversely affect functionality of the system.

In some example embodiments, the method may further include generating a fault code identifying a location of the deficiency; storing the fault code in a non-volatile memory; and communicating the fault code to an external system via a data bus.

In some example embodiments, measuring the direct current voltage may include using voltage sensors having an input impedance such that the voltage sensors draw negligible current compared to a leakage current of the semiconductor switches.

In some example embodiments, the method may further include detecting whether the deficiency is present on an adaptive testing schedule by selecting between a fast test mode and a comprehensive test mode based on one or more of: a time since last test, a presence of previous fault indicators, or system usage patterns, wherein in the fast test mode, the measuring measures the direct current voltage without disconnecting a load from the controller such that the deficiency is detected without identifying a location of the deficiency, and in the comprehensive test mode, the method further includes disconnecting the load from the controller; and identifying the location of the deficiency in response to disconnection of the load.

In some example embodiments, detecting whether the deficiency is present may include comparing the direct current voltage across each of the semiconductor switches to a threshold voltage; and identifying a short circuit deficiency, in response to the direct current voltage being less than the threshold voltage; and identifying an open-circuit deficiency, in response to the direct current voltage being less than or greater than the threshold voltage, wherein the threshold voltage for each semiconductor switch may be the same or different values.

In some example embodiments, the measuring the direct current voltage may include measuring the direct current voltage across each of the semiconductor switches, while each of the semiconductor switches are commanded off to identify whether the short circuit deficiency is present.

In some example embodiments, the method may further include disconnecting a load from the controller; and identifying a location of the short circuit deficiency in response to disconnection of the load.

In some example embodiments, the measuring the direct current voltage may include, after disconnecting the load from the controller, remeasuring the direct current voltage across each of the semiconductor switches, while each of the semiconductor switches are commanded off to identify the location of the short circuit deficiency.

In some example embodiments, detecting whether the deficiency is present may include measuring the direct current voltage across one or more of the semiconductor switches before a switch command for the one or more of the semiconductor switches is given; measuring the direct current voltage across the one or more of the semiconductor switches after a switch command for the one or more of the semiconductor switches is given; comparing the direct current voltage before the switch command to the direct current voltage after the switch command; determining if a change in the direct current voltage after the switch command is greater than or equal to a threshold value; and detecting that the deficiency is present if (i) the change in the direct current voltage is greater than or equal to the threshold value and the direct current voltage was not supposed to change by the threshold value, or (ii) the change in the direct current voltage is less than the threshold value and the direct current voltage was supposed to change by at least the threshold value, wherein the threshold value for each semiconductor switch may be the same or different values.

In some example embodiments, the detecting may detect whether an open circuit deficiency is present by activating one of the semiconductor switches only after the detecting detects that no short circuit deficiencies are present in the system; and measuring the direct current voltage across the activated switch and any of the semiconductor switches expected to be conductively connected to the activated switch.

In some example embodiments, the activating may include sequentially activating each of the semiconductor switches; and for each active switch, a same or a different subset of the semiconductor switches is monitored to determine if the open circuit deficiency exists.

In some example embodiments, in response to detecting the deficiency is present by measuring the direct current voltage, the detecting whether the deficiency is present may further include identifying a short circuit deficiency by activating one semiconductor switch at a time and monitoring whether a direct current bus voltage collapses while operating at a reduced test voltage; and determining a location of the short circuit deficiency by measuring and evaluating which converter phases a discharge current passed through.

In some example embodiments, a controller of a system may include a memory; and processing circuitry configured to detect whether a deficiency is present in the system by, providing electrical energy to semiconductor switches of the controller, measuring a direct current voltage across each of the semiconductor switches in the controller, and detecting that the deficiency is present, if the direct current voltage measured across any of the semiconductor switches is higher or lower than a threshold voltage.

In some example embodiments, the processing circuitry may be further configured to generate an alert in response to detecting the deficiency, wherein the alert includes one or more of a visual display message, an illuminated indicator, or an audible alarm.

In some example embodiments, the system may include an electrical load, the electrical load being one of an internal permanent magnet motor, a switch reluctance motor, a brake chopper resistor, or a filter network.

In some example embodiments, the processing circuitry may be further configured to inhibit a voltage supply from providing an operational voltage level to a direct current bus of the system, in response to detecting that the deficiency is present.

In some example embodiments, the system may include a propulsion motor operating as an electrical load, and wherein inhibiting providing of the operational voltage level inhibits the propulsion motor from driving a vehicle.

In some example embodiments, the deficiency may include one or more of i) an open circuit of an activated semiconductor switch, ii) a short circuit of a deactivated one of the semiconductor switches, iii) a failure of a connection of the controller with an electrical load, or iv) a failure of the electrical load.

In some example embodiments, the processing circuitry may be configured to provide the electrical energy by providing one or more test voltage levels to a direct current bus, the test voltage levels being equal to or less than a maximum level of an operational voltage level of the system; and measuring the direct current voltage across each of the semiconductor switches while the test voltage levels are applied to the direct current bus.

In some example embodiments, the processing circuitry may be further configured to increase the electrical energy supplied from the one or more test voltage levels to the operational voltage level, only after determining that there are no deficiencies present in the system; or that the deficiencies detected will not adversely affect functionality of the system.

In some example embodiments, the processing circuitry may be further configured to generate a fault code identifying a location of the deficiency; store the fault code in a non-volatile memory; and communicate the fault code to an external system via a data bus.

In some example embodiments, the processing circuitry may be configured to measure the direct current voltage using voltage sensors having an input impedance such that the voltage sensors draw negligible current compared to a leakage current of the semiconductor switches.

In some example embodiments, the processing circuitry may be further configured to detect whether the deficiency is present on an adaptive testing schedule by selecting between a fast test mode and a comprehensive test mode based on one or more of: a time since last test, a presence of previous fault indicators, or system usage patterns, wherein in the fast test mode, the measuring measures the direct current voltage without disconnecting a load from the controller such that the deficiency is detected without identifying a location of the deficiency, and in the comprehensive test mode, the processing circuitry further disconnects the load from the controller; and identifies the location of the deficiency in response to disconnection of the load.

In some example embodiments, the processing circuitry may be configured to detect whether the deficiency is present by, comparing the direct current voltage across each of the semiconductor switches to a threshold voltage; and identifying a short circuit deficiency, in response to the direct current voltage being less than the threshold voltage; and identifying an open-circuit deficiency, in response to the direct current voltage being less than or greater than the threshold voltage, wherein the threshold voltage for each semiconductor switch may be the same or different values.

In some example embodiments, the processing circuitry may be configured to measure the direct current voltage across each of the semiconductor switches, while each of the semiconductor switches are commanded off to identify whether the short circuit deficiency is present.

In some example embodiments, the processing circuitry may be further configured to disconnect a load from the controller, and identify a location of the short circuit deficiency in response to disconnection of the load.

In some example embodiments, the processing circuitry may be configured to measure the direct current voltage by, after disconnecting the load from the controller, remeasuring the direct current voltage across each of the semiconductor switches, while each of the semiconductor switches are commanded off to identify the location of the short circuit deficiency.

In some example embodiments, the processing circuitry may be configured to detect whether the deficiency is present by measuring the direct current voltage across one or more of the semiconductor switches before a switch command for the one or more of the semiconductor switches is given; measuring the direct current voltage across the one or more of the semiconductor switches after a switch command for the one or more of the semiconductor switches is given; comparing the direct current voltage before the switch command to the direct current voltage after the switch command; determining if a change in the direct current voltage after the switch command is greater than or equal to a threshold value; and detecting that the deficiency is present if (i) the change in the direct current voltage is greater than or equal to the threshold value and the direct current voltage was not supposed to change by the threshold value, or (ii) the change in the direct current voltage is less than the threshold value and the direct current voltage was supposed to change by at least the threshold value, wherein the threshold value for each semiconductor switch may be the same or different values.

In some example embodiments, the processing circuitry may be configured to detect whether an open circuit deficiency is present by activating one of the semiconductor switches only after the detecting detects that no short circuit deficiencies are present in the system; and measuring the direct current voltage across the activated switch and any of the semiconductor switches expected to be conductively connected to the activated switch.

In some example embodiments, the activating may include sequentially activating each of the semiconductor switches; and for each active switch, a same or a different subset of the semiconductor switches is monitored to determine if the open circuit deficiency exists.

In some example embodiments, in response to the processing circuitry detecting the deficiency is present by measuring the direct current voltage, the processing circuitry may be further configured to, identify a short circuit deficiency by activating one semiconductor switch at a time and monitoring whether a direct current bus voltage collapses while operating at a reduced test voltage; and determine a location of the short circuit deficiency by measuring and evaluating which converter phases a discharge current passed through.

In some example embodiments, a non-transitory computer-readable medium may store instructions that, when executed by processing circuitry of a controller in a system, cause the processing circuitry to detect whether a deficiency is present in the system by providing electrical energy to semiconductor switches of the controller; measuring a direct current voltage across each of the semiconductor switches in the controller; and detecting that the deficiency is present, if the direct current voltage measured across any of the semiconductor switches is higher or lower than a threshold voltage.

### BRIEF DESCRIPTION OF THE DRAWINGS

FIG. 1 is a block diagram of a controller configured to perform switch testing coupled to an electrical load according to an example embodiment.

FIG. 2 is a block diagram of a controller configured to perform switch testing coupled to an electrical load according to another example embodiment.

FIG. 3 is a flowchart of a method of operating a controller connected to a low impedance electrical load to perform switch testing according to an example embodiment.

FIG. 4 is a flowchart of a method of operating a controller to control an electrical load to perform switch testing according to another example embodiment.

FIG. 5 is a flowchart of a method of operating a controller to control an electrical load to perform switch testing according to another example embodiment.

### DETAILED DESCRIPTION

During operation of the load, if a defect results in one or more of the system components failing in either an open state or a closed state, operation of the load (e.g., motor speed or torque) may be difficult to control, and damage can occur to the controller, the load, or both.

For example, if a high-side semiconductor switch fails in a shorted condition (short circuit between collector and emitter, or drain and source), applying full operational voltage may create an immediate current path from the positive DC bus terminal through the shorted switch to the motor winding and potentially through other phases to the negative DC bus terminal. This uncontrolled current flow at operational voltage levels (e.g., 400V-800V in automotive applications) may result in: (a) damage to the motor windings due to excessive current, potentially melting copper conductors or damaging insulation; (b) demagnetization of permanent magnets in IPM motors due to high demagnetizing currents, which is often an irreversible and costly failure; (c) thermal destruction of other semiconductor switches in the current path; or (d) damage to DC bus capacitors, bus bars, and other power electronics components. The resulting failure may require expensive component replacement and/or may pose safety risks if the defect occurs while a vehicle is in operation.

Further, if a motor winding has an open circuit condition (due to manufacturing defect, damaged connector, or broken conductor), applying operational voltage without detection may cause: (a) unbalanced phase currents leading to excessive current in the remaining intact phases; (b) generation of torque ripple and vibration that may damage mechanical components; (c) inability to properly control motor speed and torque, leading to unpredictable vehicle behavior; or (d) overheating of intact windings due to imbalanced loading. In vehicle applications, an undetected open winding can manifest as reduced power, unexpected acceleration characteristics, or complete loss of propulsion at critical moments.

Additionally, intermittent connection faults (such as partially loosened terminals, corroded connectors, or damaged cables with marginal contact) can create particularly hazardous conditions. When operational voltage is applied to an intermittent connection, the fault may initially appear to function normally but then transition to an open circuit during operation. This can cause: (a) sudden loss of phase continuity during vehicle acceleration or high-speed operation; (b) voltage spikes on the DC bus due to inductive kickback from motor windings; (c) arcing at the loose connection point, potentially causing fire hazards; or (d) cascading failures as the electrical stress from the intermittent fault affects other components. These intermittent faults may be difficult to diagnose in the field because they may not manifest during static testing but only under dynamic operating conditions.

Once full operational voltage is applied, the fault conditions may immediately begin causing damage. Accordingly, conventional protective measures such as over-current shutdown may react too slowly and, thus, may not safely discriminate between normal system start-up behavior and fault conditions until damage has already begun to occur. Thus, there is a need for an improved method and controller for an electric load with switch testing that can detect such deficiencies before they cause operational problems or damage.

### System Architecture—Two-Phase Configuration

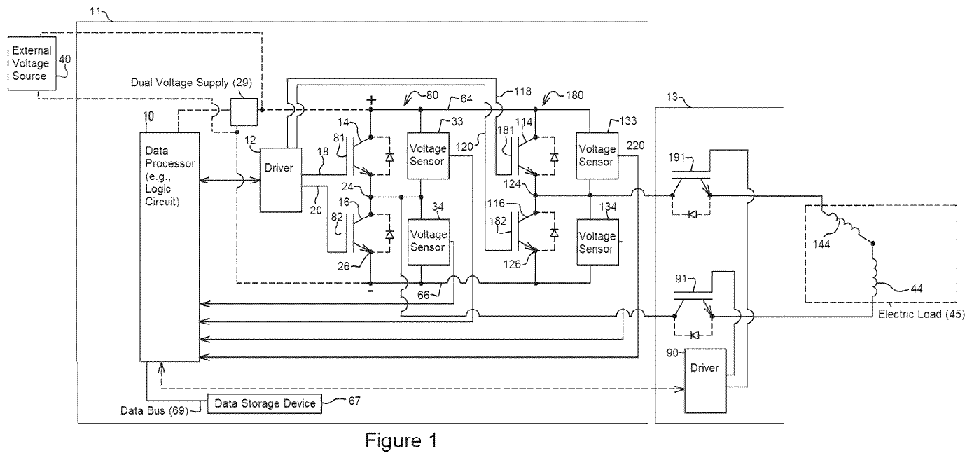

FIG. 1 is a block diagram of a controller configured to perform switch testing coupled to an electrical load according to an example embodiment.

In accordance with one example embodiment, FIG. 1 discloses a system, inverter or controller (11) for controlling an electrical load (45), where the controller (11) is configured to detect a deficiency in one or more components of the system while operating in a test mode, prior to entering an operational mode. For example, a deficiency may include a short circuit failure mode and/or open-circuit failure mode of one or more semiconductor devices in the controller (11) or a deficiency may include an open circuit failure of the electrical load (45) or the connections between the controller (11) and the electrical load (45). The electrical load (45) may be a single phase or multiple phase load. The electrical load (45) may be an internal permanent magnet motor, a switch reluctance motor, a brake chopper resistor, or a filter network. However, example embodiments are not limited thereto. As illustrated, the system, aside from the electrical load (45), may be referred to as an inverter or a controller (11).

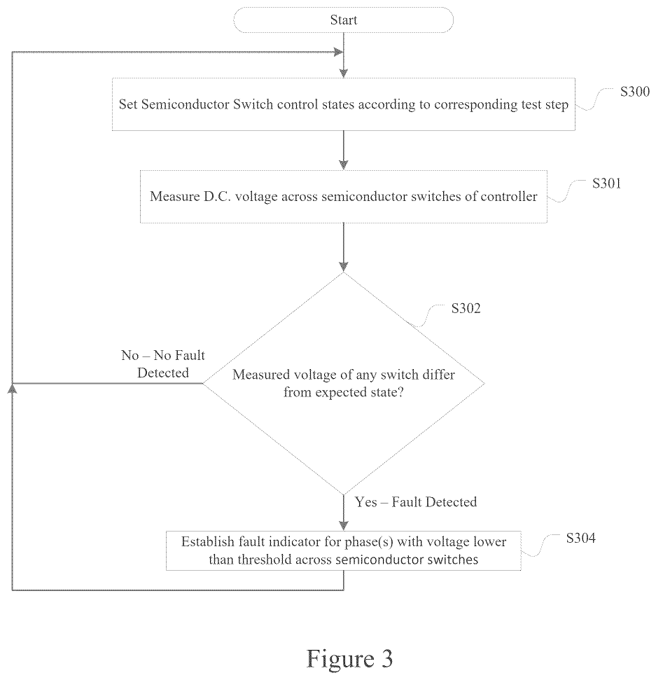

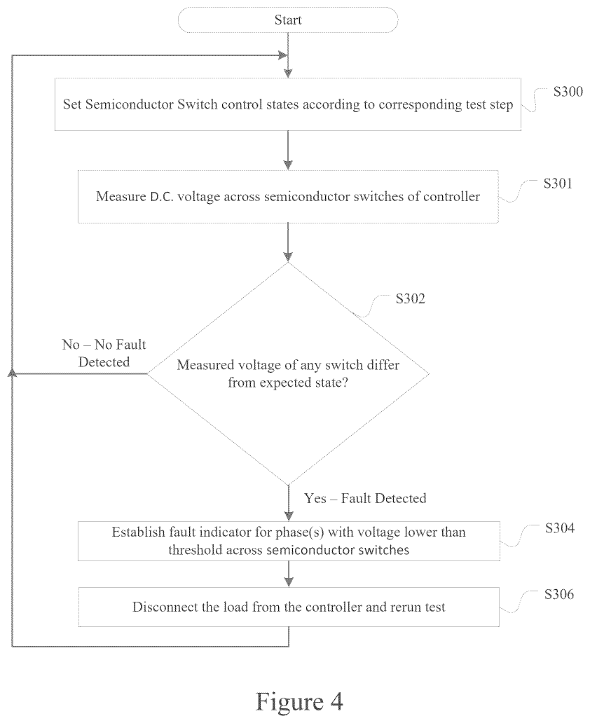

The controller (11) may test for a deficiency while operating the system at a test voltage. In some example embodiments, the test voltage may be the full operational voltage. Testing at full operational voltage provides several advantages. First, it may eliminate the need for a dual voltage supply or pre-charge circuit, simplifying the system architecture and reducing component count and cost. Second, full operational voltage testing may enable the system to transition immediately to operational mode upon successful completion of testing, without requiring a voltage ramp-up phase, thereby reducing the delay before the system becomes ready for use. Third, testing at operational voltage may provide more accurate detection of voltage-dependent failure modes that might not manifest at reduced voltage levels, such as partial short circuits or high-resistance faults that may only become problematic at higher voltages and currents. Fourth, because the disclosed voltage-based testing method does not require current flow and does not impact DC link voltage, the test can be performed at full operational voltage without discharging the system—particularly advantageous for battery electric vehicles where maintaining battery state of charge is critical. Fifth, the ability to test at operational voltage removes timing restrictions between test execution and battery connection, enabling diagnostic verification at any point in the operational cycle. Sixth, voltage-based testing at operational levels causes no device degradation from repeated testing, allowing frequent diagnostics without reducing component life The testing methods discussed below with reference to FIGS. 3 and 4 may be particularly well-suited for full operational voltage testing because they rely on voltage measurements to verify that there are no short circuit faults prior to turning on the switches and allowing current to flow, thereby reducing the chance of damage even when testing at full operational voltage.

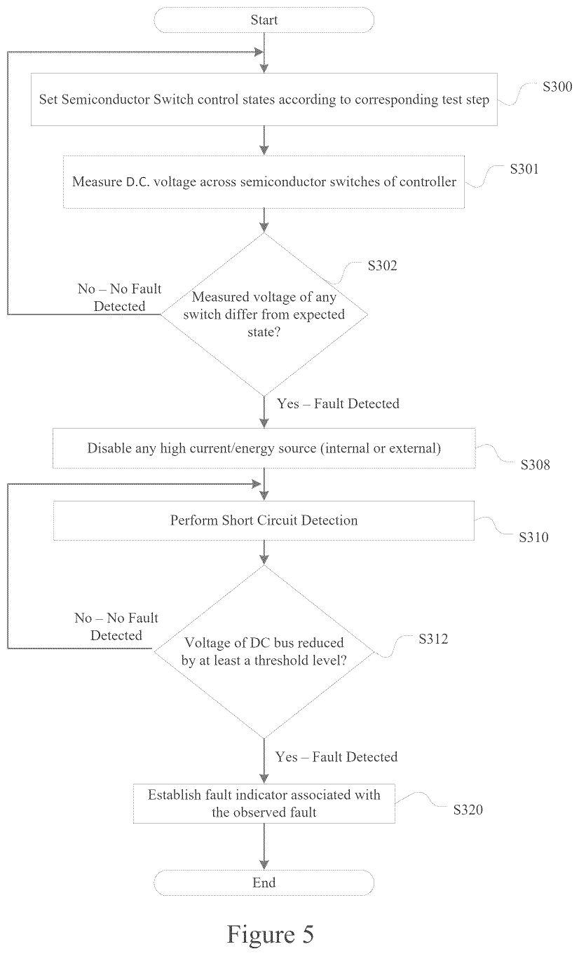

In other example embodiments, the controller (11) may test for a deficiency while operating the system at a reduced test voltage level prior to applying the full operational voltage. This reduced-voltage approach may be utilized when performing any of the testing methods discussed below with reference to FIGS. 3-5, but may be especially useful when performing the test method of FIG. 5, where current flows when the switches are turned on in a specific order to verify that they all function correctly and have not failed open. By limiting the voltage during these current-flowing tests, the reduced-voltage approach provides an additional safety margin that further limits fault current to safe levels according to Ohm's law (I=V/R), thereby reducing stress on components during testing. This two-stage voltage approach (reduced test voltage followed by full operational voltage) may enable comprehensive fault detection, including both short circuit and open circuit faults, while maintaining all fault conditions within a safe operating region where permanent damage is even less likely to occur.

The controller (11) may be implemented in various applications including, but not limited to, electric vehicle propulsion systems (e.g., passenger vehicles, commercial trucks, buses, agricultural equipment, construction equipment, material handling vehicles), industrial motor drives (e.g., pumps, fans, compressors, conveyors, machine tools), renewable energy systems (e.g., wind turbine generators, solar inverters), HVAC systems, or appliance motor controls. In electric vehicle applications, the controller (11) may be configured to control a traction motor that provides propulsion power to drive wheels or tracks, with the electrical load (45) comprising one or more motors rated for vehicle propulsion (e.g., 50 kW to 300 kW or higher). The pre-operational testing capability of the controller (11) may enhance vehicle safety by testing for semiconductor switch deficiencies before the vehicle begins operation, thereby inhibiting potential loss of propulsion or uncontrolled motor behavior.

In FIG. 1, a data processor (10) is coupled to a driver (12) and a dual voltage supply (29). The driver (12) may include a semiconductor drive circuit that drives or controls semiconductor switches (81, 82, 181, 182) to generate control signals for the electrical load (45) coupled to an inverter circuit (80). The driver (12) may comprise gate driver integrated circuits, discrete gate driver transistors, or other semiconductor drive circuitry capable of providing sufficient voltage and current to the control terminals (gates or bases) of the semiconductor switches to transition them between conducting and non-conducting states. The driver (12) receives control signals from the data processor (10) and converts them into appropriate drive signals for the semiconductor switches (81, 82, 181, 182).

The inverter circuit (80) may convert a direct current input signal from a direct current bus (64, 66) to one or more alternating current output signals at output terminal (24). The inverter circuit (80) may include the semiconductor switches (81, 82, 181, 182) and associated components used to perform DC-to-AC conversion. The direct current bus (64, 66) provides electric energy to the controller (11) or inverter circuit (80), including its semiconductor switches (81, 82, 181, 182). The direct current bus comprises a positive direct current terminal (64) and a negative direct current terminal (66), which may also be referred to as DC+ and DC−, respectively. In turn, the inverter circuit (80) is coupled to the electrical load (45) or motor windings (44, 144, and 244). Although a motor with windings (44, 144, and 244), illustrated as Wye (Y) fed configuration, is used for illustrative purposes, example embodiments are not limited thereto and other arrangements and types of loads are possible. For example, the electrical load (45) may alternatively include a Delta-connected three-phase motor, multiple three-phase or single phase motors connected in parallel, a motor with accessible neutral point, a three-phase or single phase transformer, a three-phase or single-phase rectifier, and/or a DC motor.

The dual voltage supply (29) may be capable of providing electrical energy to the DC bus (64, 66) at multiple voltage levels. For example, as discussed above, the controller 11 may test for a deficiency while operating the system at the full operational voltage, and, thus the dual voltage supply (29) may only output a single operational voltage. However, in some example embodiments, a lower test voltage level may optionally be used during the test mode, and a higher operational voltage level may be used during normal operation of the electrical load (45). In this case, the test voltage level may be selected to be sufficiently high to enable reliable voltage measurements and deficiency detection, while being low enough to limit current flow through any defective switches to levels that will not cause damage to the electrical load (45), the semiconductor switches (81, 82, 181, 182), or other components of the controller (11) when the switches are turned on in a specific order to verify that the switches function correctly and have not failed open.

In some example embodiments, this lower test voltage may be in the range of 5% to 50% of the operational voltage, such as 10% to 30% of the operational voltage. For example, if the operational voltage is 400 volts, the test voltage may be approximately 40 to 120 volts. The specific test voltage value may be selected based on factors including the type of electrical load, the characteristics of the semiconductor switches, the sensitivity of the voltage sensors (33, 34, 133, 134), and/or the desired safety margin.

The data processor (10) may provide a control signal or control data to a dual voltage supply (29) to control the voltage level output by the dual voltage supply (29). An external voltage source (40), providing a voltage as high as the operational limits of the controller (11) (e.g. an EV Battery) can also be used instead of the dual voltage supply (29). When an external voltage source (40) is used and a reduced test voltage is beneficial to verify that the switches function correctly and have not failed open, the reduced test voltage may be achieved through various means including, but not limited to, a pre-charge circuit with current-limiting resistor, a DC-DC converter that steps down the external voltage, pulse-width modulation control to reduce the effective voltage, a series impedance that limits current and thereby reduces voltage under test conditions, or an isolated power supply that draws power from a source other than the external voltage source (40).

The data processor (10) may include ‘processing circuitry,” such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), a digital signal processor, a microcomputer, a field programmable gate array (FPGA), a System-on-Chip (SoC), a programmable logic unit, a microprocessor, application-specific integrated circuit (ASIC), etc.

For example, in some example embodiment, upon power up or initial turn on of the controller (11), the data processor (10) may enter into the test mode or a diagnostic mode while voltage is supplied by the dual voltage supply (29) or the external voltage source (40), while the data processor runs through a test program, routine, software instructions, or logic in which one or more semiconductor devices (81, 82, 181, 182) are selectively activated and the direct current voltage across each switch is observed by voltage sensors (33, 34, 133, 134) to determine whether any deficiency exists in respective ones of the semiconductor switches (81, 82, 181, 182) (e.g., for short circuit or open circuit failure modes), the cables/harnessing connecting the controller (11) to the electrical load (45) (e.g., open circuit of connector or cable), or the electrical load itself (45) (e.g., open circuit of a winding). In other example embodiments, the test mode or diagnostic mode may be programmed or scheduled to occur based on a calendar date, a number of power-up or power-down cycles, or control data input (e.g., contact closure or logic input) from an external device. For example, the test mode may be overridden where the electrical load (45) is installed on a vehicle that powers down the controller (11) at a stop light to conserve electrical energy or extend battery life.

### Inverter Circuit Configuration

The inverter circuit (80) includes power electronics, such as switching semiconductors (81, 82, 181, 182) to generate, modify and control pulse-width modulated signals or other alternating current signals (e.g., pulse, square wave, sinusoidal, or other waveforms) applied to the electrical load (45). An output stage of the inverter circuit (80) provides a pulse-width modulated signal or other alternating current signal for control of the electrical load (45). The inverter circuit (80) inverts or transforms direct current received thereto into one or more alternating current output signals for application to a corresponding phase or winding (44, 46, or 48) of the electrical load (45).

For each output phase (80, 180, etc.), the controller (11) or inverter includes a pair of semiconductor switches (a first pair of 81, 82; a second pair of 181, 182; etc.). In one embodiment, the semiconductor switches (81, 82, 181, 182) may include insulated gate bipolar transistors (IGBT), field effect transistors, power transistors, or other semiconductor devices. Each semiconductor switch includes a control terminal (such as a gate for IGBT or MOSFET devices, or a base for bipolar transistor devices) and two switched output terminals (such as collector and emitter for IGBT devices, or drain and source for MOSFET devices).

The controller (11) or inverter may include a first pair of semiconductor switches (81, 82) including a high side switch (81) and a low side switch (82) for a first phase (80) of the controller (11). In the first phase (80), the high side switch (81) may be referred to as a high side switch because one of its switched output terminals (e.g., collector or drain, among output terminals (14, 24)) may be connected to a positive direct current terminal (64) of the direct current bus. The other switched output terminal of the high side switch (81) (e.g., emitter or source, at terminal 24) is connected to an output terminal of the first phase. The low side switch (82) may be referred to as a low side switch because one of its switched output terminals (e.g., emitter or source, among output terminals (16, 26)) may be connected to a negative direct current terminal (66) of the direct current bus. The other switched output terminal of the low side switch (82) (e.g., collector or drain, at terminal (24)) is connected to the output terminal of the first phase. Thus, the output terminal (24) is common to both the high side switch (81) and the low side switch (82), forming a half-bridge configuration where the two switches are connected in series between the DC bus terminals (64, 66) with the output taken from the junction point (24) between them.

The controller (11) or inverter may further include a second pair of semiconductor switches (181, 182) including a high side switch (181) and a low side switch (182) for a second phase (180) of the controller. In the second phase (180), the high side switch (181) may be referred to as a high side switch because one of its switched output terminals (e.g., collector or drain, among output terminals (114, 124)) may be connected to a positive direct current terminal (64) of the direct current bus. The low side switch (182) may be referred to as a low side switch because one of its switched output terminals (e.g., emitter or source, among output terminals (116, 126)) may be connected to a negative direct current terminal (66) of the direct current bus. The other switched output terminal of the low side switch (182) (e.g., collector or drain, at output terminal (124)) is connected to the output terminal of the second phase. Thus, the output terminal (124) is common to both the high side switch (181) and the low side switch (182), forming a second half-bridge configuration.

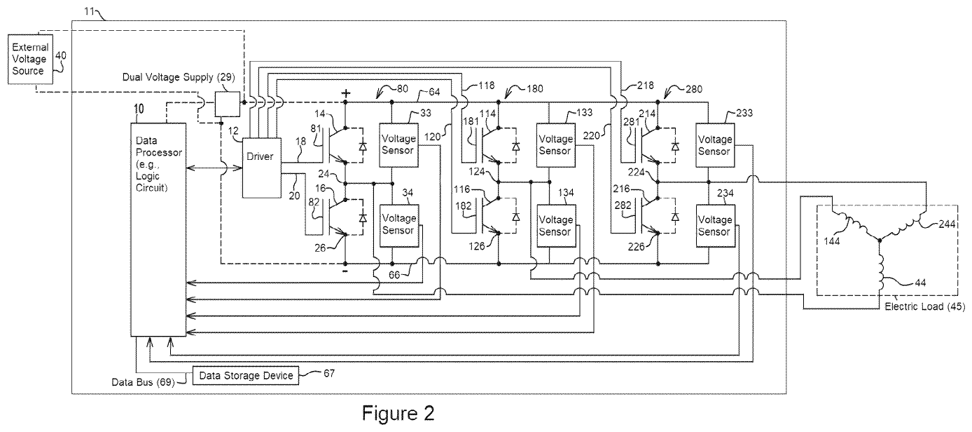

In some example embodiments, a load disconnection stage (13) may be included between the inverter circuit, inverter, or controller (11) and the electrical load (45). The load disconnection stage (13) may include one or more controllable semiconductor switching devices, such as first and second switches (91, 191), each optionally including an anti-parallel diode and being driven by a gate driver (90). The switches (91, 191) may be arranged in series with the electrical load (45) and configured to selectively couple or decouple under the control of the gate driver (90) and/or the controller (11). However, example embodiments are not limited thereto. In some example embodiment the load disconnection stage (13) may be omitted, as illustrated in FIG. 2 with respect to a three-phase load, but may equally be applied to any load.

Although FIG. 1 illustrates a two-phase controller for controlling an electrical load (45), a controller may generally have one or more phases. In one example embodiment, the inverter circuit, inverter, or controller (11) is powered by a direct current (DC) voltage bus (64, 66, collectively). For example, in FIG. 1, a direct current voltage bus (64, 66) is coupled to collector and emitter terminals (or source and drain terminals) of the semiconductor switches (81, 82, 181, 182) for each phase. The input terminal (18, 20, 118, 120) of each semiconductor switch (81, 82, 181, 182) is coupled to the driver (12). The input terminal (18, 20, 118, 120) of each semiconductor switch may include a gate terminal (for IGBT or MOSFET devices) or a base terminal (for bipolar transistor devices), for example. The output terminal (24, 124) of each semiconductor switch pair is coupled to a terminal of a motor winding (44, 144, or 244). As illustrated in FIG. 1, the output terminal (24, 124) of each phase may be located at the junction of the high side switch and the low side switch for a particular phase. Each different phase (80, 180) of the controller (11) may be associated with a corresponding phase winding (44, 144, or 244) of the electrical load (45).

### Voltage Sensing System

Measuring circuits or voltage sensors (33, 34, 133, 134) are used to measure the direct current voltage across each power semiconductor switch (81, 82, 181, 182). The voltage sensors (33, 34, 133, 134) may be configured to measure the lower voltage level of the test mode, the higher level of the test mode, or both. Each voltage sensor measures the voltage between the switched output terminals of its associated semiconductor switch. For example, voltage sensor (33) measures the voltage between terminals 14 and 24 of high side switch (81), voltage sensor (34) measures the voltage between terminals 24 and (26) of low side switch (82), voltage sensor (133) measures the voltage between terminals (114) and (124) of high side switch (181), and voltage sensor (134) measures the voltage between terminals (124) and (126) of low side switch (182).

The voltage sensors (33, 34, 133, 134) can detect a material deviation or transient deviation (e.g., decrease or collapse) of the direct current voltage that may occur when one or more semiconductor switches are activated (81, 82, 181, 182). For example, the voltage sensor (33) may detect whether or not the voltage level (e.g., between terminals (14), (24)) decreases by at least a threshold level (e.g., stored in the data storage device (67)) while turning on the particular switch (e.g., high side switch (181)). A “material deviation” may be defined as a voltage change of sufficient magnitude to reliably indicate a change in circuit conditions, such as a voltage drop of at least 10%, 20%, 50%, or substantially all of the measured voltage. In contrast, a “transient deviation” may refer to a rapid voltage change occurring over a short time period (e.g., microseconds to milliseconds) in response to a switch state change.

The voltage sensors (33, 34, 133, 134) or measuring circuits provide a high input impedance relative to the semiconductor switches (81, 82, 181, 182) and the direct current voltage bus (64, 66) such that the voltage sensors (33, 34, 133, 134) or the measuring circuits do not perturb the performance of the semiconductor switch or draw material current (e.g., emitter current or collector current) from the semiconductor switch or the direct current voltage bus (64, 66).

The high input impedance characteristics of the voltage sensors (33, 34, 133, 134) may inhibit the voltage sensors from perturbing the circuit being measured and enables detection of subtle fault conditions. During the test mode, when semiconductor switches are commanded to the off state, the impedance between the switch terminals may be dominated by the leakage resistance of the semiconductor device, which may be on the order of 100 kΩ to several megohms for modern IGBT or MOSFET switches. If the voltage sensor input impedance were low (e.g., 10 kΩ), the sensor may act as a parallel resistance that significantly loads the circuit, causing the measured voltage to differ from the true voltage. For example, if the DC bus voltage is 400V, the switch leakage resistance is 1 MΩ, and the sensor input impedance is 10 kΩ, under certain failure conditions the measured voltage would be approximately 4V rather than the expected 400V, leading to a false indication of a short circuit fault. By maintaining sensor input impedance at 1 MΩ or higher (preferably 10 MΩ or higher), the sensor draws negligible current compared to the switch leakage current, increasing measurement accuracy.

For example, the measuring circuits may include high impedance voltage sensors that use one or more operational amplifiers configured as voltage followers or differential amplifiers for measurement of an input voltage and optional comparison of an input voltage to a reference voltage.

The reference voltage may be provided by a battery, a voltage regulator, or a zener diode, or a precision voltage reference integrated circuit, for example. In one configuration, the output of the voltage sensor may be coupled to an analog-to-digital converter to provide a suitable digital input for the data processor (10). The analog-to-digital converter may have a resolution of 8 bits, 10 bits, 12 bits, 16 bits, or higher, selected to provide adequate measurement precision for the expected voltage ranges.

The measuring circuits or voltage sensors (33, 34, 133, 134) may provide an analog output or a digital output of the magnitude of the voltage, polarity of the voltage, or both. As shown in FIG. 1, in some example embodiment, the voltage sensors (33, 34, 133, 134) are coupled to the data processor (10) via an output (220) to provide a digital output thereto. However, example embodiments are not limited thereto and the voltage sensors (33, 34, 133, 134) or measuring circuits may instead provide an analog output to an analog-to-digital converter (not shown) interposed between the voltage sensors (33, 34, 133, 134) and the inputs of the data processor (10).

The measuring circuits or voltage sensors (33, 34, 133, 134) are configured to detect a decrease or collapse in the direct current voltage when a semiconductor switch (81, 82, 181, 182) is activated or turned on. Accordingly, the measuring circuits or voltage sensors may identify a fault or short circuit in a semiconductor switch (81, 82, 181), or any parallel diodes, such that in the test mode the current initially associated with the early detected short circuit or fault may be insufficient to damage the controller (11) or the electrical load (45).

In some cases, the data processor (10) may lower (e.g., slightly, but with suitable bias to activate or turn on the switch) the input voltage to the gate or base input of the semiconductor switch (81, 82, 181, 182) with a greater than typical or normal leakage current to ensure the semiconductor device is operating within a desired operational zone that reduces (or, alternatively, minimizes) any fault or short circuit current in the switched output terminals of the semiconductor device. This technique may involve operating the switch in a partially-on or linear region rather than fully saturated, thereby limiting the current that can flow through a short circuit path while still enabling detection of voltage changes indicative of switch deficiencies.

### Driver and Control Components

The driver (12) provides digital signals for activating the semiconductor switches (82, 181, 182) in accordance with a desired input signal or control signals from the data processor (10). For example, during operation of the electrical load (45) in an operational mode, the input signals to the semiconductor devices of the inverter may correspond to a desired sinusoidal signal, a desired square wave signal, a desired alternating current signal, or another command signal, which the driver (12) converts to appropriate gate or base drive signals for the semiconductor switches. The driver (12) may implement pulse-width modulation (PWM), space vector modulation (SVM), or other modulation schemes to generate the switching patterns. During the diagnostic mode or the test mode, the input signals to the driver (12) from the data processor (10) provide control commands to selectively activate one or more of the semiconductor switches (82, 181, 182) according to a desired test sequence to prevent damage to phases of the controller (11), the electrical load (44, 46, or 48), or permanent magnets in the case of an electric motor.

### Data Processing and Storage

In one example embodiment, the data processor (10) may include an electronic data processor, a microprocessor, a microcontroller, a programmable logic array, a field programmable gate array (FPGA), a logic circuit, an arithmetic logic unit, an application specific integrated circuit (ASIC), a digital signal processor (DSP), a proportional-integral-derivative (PIO) controller, or another data processing device. Further, the data processor (10) may be coupled to a data storage device (67) via a data bus (69).

The data storage device (67) may include electronic memory, non-volatile random access memory (NVRAM), electrically erasable programmable read-only memory (EEPROM), flash memory, an optical storage device, a magnetic storage device, a hard disk drive, an optical disc drive, or another device for storing digital data or analog data. The data storage device (67) may store a look-up table, data base, file, inverted file, or another data structure with voltage threshold levels, voltage ranges, or material voltage decreases for the direct current switch voltage level that indicates a short circuit failure mode or fault in a semiconductor switch (82, 181, 182). The data storage device (67) may store a look-up table, data base, file, inverted file, or another data structure with the corresponding voltage feedback representing each possible deficiency of the system, indicating an open circuit failure mode or a short circuit failure mode in a semiconductor switch (82, 181, 182) or electrical load (45). For example, the data storage device (67) may store threshold values such as: (a) a minimum acceptable voltage across a switch when in the off state (e.g., 90% of DC bus voltage), below which a short circuit is indicated; (b) a minimum voltage collapse amount when creating a test short circuit path (e.g., bus voltage must drop by at least 50%), absence of which indicates an open circuit; and (c) correlation patterns between multiple phase voltage measurements that distinguish switch faults from sensor faults or load faults.

### Three-Phase Configuration

FIG. 2 is a block diagram of a controller configured to perform switch testing coupled to an electrical load according to another example embodiment.

As shown in FIG. 2, the electrical load (45) may be a three-phase load, and the controller (11) may include a third phase (280), in addition to the first and second phases phase (80, 180). Like the first and second phases (80, 180), the third phase (280) may include a third pair of semiconductor switches (281, 282) including a high side switch (281) and a low side switch (282). The high side switch (281) may be referred to as a high side switch because one of its switched output terminals (e.g., collector or drain, among output terminals (214, 224)) may be connected to a positive direct current terminal (64) of the direct current bus. The other switched output terminal of the high side switch (281) (e.g., emitter or source, at terminal (224)) is connected to an output terminal of the third phase. The low side switch (282) may be referred to as a low side switch because one of its switched output terminals (e.g., emitter or source, among output terminals (216, 226)) may be connected to a negative direct current terminal (66) of the direct current bus. The other switched output terminal of the low side switch (282) (e.g., collector or drain, at terminal (224)) is connected to the output terminal of the third phase.

Further, the third phase (280) may include voltage sensors (233) and (234) used to measure the direct current voltage across each power semiconductor switch (281, 282). For example, voltage sensor (233) may measure the voltage between terminals (214) and (224) of high side switch (281), and voltage sensor (234) may measure the voltage between terminals (224) and (226) of low side switch (282).

The examples illustrated in FIGS. 1 and 2 may be expanded to four or more phases. For example, dual three-phase systems (six phases total) may be used for higher power applications or for redundancy in safety-critical applications. Each additional phase may include a corresponding pair of high-side and low-side semiconductor switches, voltage sensors for measuring voltage across each switch, and connections to an additional phase winding of the electrical load.

In vehicle propulsion applications, a three-phase configuration as shown in FIG. 2 is commonly used for electric traction motors. The controller (11) may be integrated within an electric vehicle's powertrain system, receiving high-voltage DC power from a battery pack via the external voltage source (40) or DC bus (64, 66), and providing three-phase AC power to a traction motor (electrical load (45)) that drives the vehicle wheels or tracks. The pre-operational testing capability disclosed herein may test whether the propulsion system is functioning correctly before the vehicle begins moving, thereby enhancing safety and reliability. In the event that a deficiency is detected during testing, the controller (11) may inhibit the vehicle from entering a ready-to-drive state and/or may alert the operator or vehicle control system to the fault condition. In some example embodiments, the alert may be visual display message, an illuminated indicator, or an audible alarm.

As discussed above, and as illustrated in FIG. 2, in some example embodiments the load disconnection stage (13) may be omitted when the electrical load (45) does not need to be isolated from the inverter circuit or controller (11).

### Fault Detection—Short and Open Circuits

FIG. 3 is a flowchart of a method of operating a controller connected to a low impedance electrical load to perform switch testing according to an example embodiment.

In operation S300, the data processor (10) or the measuring circuits or voltage sensors (33, 34, 133, 134) may set semiconductor switch control states according to a corresponding test step. For example, in an initial baseline test, the data processor (10) may command all semiconductor switches (81, 82, 181, 182) to an off state (non-conducting) via control signals to the driver (12). The driver (12) then applies appropriate gate or base voltages to maintain all switches in the off state.

In operation S301, the data processor (10) or the measuring circuits or voltage sensors (33, 34, 133, 134) may measure the voltage across each of the semiconductor switches in the controller. For example, voltage sensor (33) measures the voltage across high side switch (81), voltage sensor (34) measures the voltage across low side switch (82), voltage sensor (133) measures the voltage across high side switch (181), and voltage sensor (134) measures the voltage across low side switch (182). If the controller includes additional phases (such as third phase (280) in FIG. 2), voltage measurements may also be taken across the switches in those phases.

In operation S302, the data processor (10) or the voltage sensor (33, 34, 133, 134) may detect whether the measured voltage of any switch differs from expected states. In some example embodiments, the data processor (10) or voltage sensor (33, 34, 133, 134) may detect whether the measured voltage of any switch differs from expected states using different methods.

For example, in one method, the data processor (10) may measure the voltage(s) across one or more switches, compare the measured voltage(s) against a desired (or, alternatively, a predetermined) voltage threshold stored in data storage device (67), and verify that the outcome of that comparison aligns with the expected result for that specific test step. For example, when all switches are commanded to the off state and no short circuit faults are present, each switch should exhibit a voltage substantially higher than the ON-state voltage (e.g., greater than 10V or greater than 10% of bus voltage). The voltage sensor (33) may detect whether or not the voltage level across switch (81) is below a threshold value stored in data storage device (67). If a switch is shorted (short circuit fault), the voltage across that switch will be substantially zero or very low (e.g., less than 10V or less than 10% of the bus voltage, such as less than 40V for a 400V bus). The voltage threshold may be an absolute voltage value (e.g., 10V regardless of bus voltage, or 40V for a 400V bus) or a percentage of the measured bus voltage (e.g., 10% of bus voltage). If the comparison outcome matches the expected result for the test step, no fault is indicated. If the comparison outcome does not match the expected result, a fault is indicated.

In another method, the data processor (10) may measure the voltage before a switch command is given and then again after the switch command is given, compare the two values to determine if the voltage changed by more than a specific threshold value stored in data storage device (67). This method detects whether the expected voltage change occurred in response to the switch state change. The evaluation proceeds as follows:
(a) if the voltage changed by more than the expected deviation and it was supposed to change, no fault is indicated;
(b) if the voltage changed by more than the expected deviation and it was not supposed to change, a fault is indicated;
(c) if the voltage did not change by more than the expected deviation and it was supposed to change, a fault is indicated; and
(d) if the voltage did not change by more than the expected deviation and it was not supposed to change, no fault is indicated.

For example, in a test where high-side switch (81) is commanded on while all other switches remain off, if no faults are present, the voltage across low-side switch (82) should increase substantially (e.g., by at least 50% of bus voltage or by at least a predetermined threshold such as 180V for a 400V bus), while the voltage across high-side switch (81) should decrease substantially. The before-and-after method may be particularly useful for detecting open-circuit faults where the absolute voltage level may be ambiguous but the expected voltage change provides clear fault indication.

Either method may be used independently or in combination depending on the specific test step being performed. The absolute threshold comparison method may be preferred for baseline testing where all switches are commanded off and expected voltages are well-defined. The before-and-after comparison method may be preferred for dynamic testing where switches are activated sequentially and the voltage response to state changes provides the primary diagnostic information. The data storage device (67) may store threshold values appropriate for both methods, including absolute voltage thresholds (e.g., 10V, 40V, 90% of bus voltage) and voltage change thresholds (e.g., 50% of bus voltage, 180V for a 400V system).

If the measured voltage is higher than the desired (or, alternatively, the predetermined) voltage threshold, the short circuit test has passed and the system will continue on to the “open circuit” test (repeat S300 with different switch control states). Short circuit testing should be run first, because running the open circuit tests when there is a short circuit in the system may cause damage.

If the measured voltage is lower than the desired (or, alternatively, the predetermined) voltage threshold, the data processor (10) or the voltage sensor (33, 34, 133, 134) may communicate that a short circuit deficiency exists to the data processor (11) or store a fault indicator in data storage device (67). If the measured voltage is higher than the desired (or, alternatively, the predetermined) voltage threshold, the data processor (10) or the voltage sensor (33, 34, 133, 134) may communicate that an open circuit deficiency exists to the data processor (11) or store a fault indicator in data storage device (67).

In operation S304, the data processor (10) may establish fault indicators based on the type of deficiency detected. In some iterations of the method, short circuit faults may be identified and set, while in other iterations, open-circuit faults may be identified and set, as the method is capable of identifying both types of deficiencies. For example, the data processor (10) may establish a “high side short circuit” fault indicator for any controller phase (80, 180) that contains a high side semiconductor switch having a voltage across the semiconductor switch that is less than the desired (or, alternatively, the predetermined) voltage threshold. Further, the data processor (10) may establish a “low side short circuit” fault indicator for any controller phase (80, 180) that contains a low side semiconductor switch having a voltage across the semiconductor switch that is less than the desired (or, alternatively, the predetermined) voltage threshold. Additionally, the data processor (10) may establish an “open-circuit” fault indicator for any controller phase, switch, or load phase where the expected voltage change did not occur in response to a switch command, indicating an open circuit in the switch, in the electrical load winding, or in the connections between the controller and the load. After completing operation S304, the method may include changing the switch states for the next iteration of testing, if required, and iteratively measuring the voltage across the switches, comparing the results against expected voltage values based on the commanded state of the switches, setting faults as appropriate based on the results of the comparison.

As discussed above, in some example embodiments, the establishment of a fault indicator may include setting a flag to inhibit the vehicle from entering a ready-to-drive state and/or may include generating an alert for the operator or vehicle control system to the fault condition. In some example embodiments, the fault indicators may be stored in data storage device (67) along with associated diagnostic information such as which switches were being tested, measured voltage values, timestamp, and other relevant data.

Further, as discussed above, in some example embodiments, the controller (11) may provide an indication of a fault and, in the case of a “non-serviceable” component, the “short circuit” or “open-circuit” fault indicator may be sufficient to decide that the entire component is damaged and needs to be replaced.

While the test(s) described above can be used to identify if there is a general problem with the entire system, it may be difficult to identify exactly where the failure has occurred. However, as discussed in more detail below, fault localization through load disconnection can be used to further diagnose the specific device that has failed. For controllers with serviceable or replaceable switch modules, it may be desirable to identify the specific switch which has the deficiency. For example, for some controllers (11) it may be possible to repair specific switches within the controller. It may also be useful to diagnose which phase in the electrical load (45) is contributing to the identified deficiency. The methods of FIGS. 4 and 5 are well suited for localization of a short or open circuit fault in the load (45) and/or controller (11) and identifying a particular deficient semiconductor switch or load phase with a short or open circuit between the controlled or switched terminals.

For controllers with multi-phase loads, the methods of FIGS. 3, 4, and 5 may eliminate or reduce false positives for short or open circuit of the switches by using all high side or low side voltage measurements of the voltage sensors (33 & 133 or 34 & 134) as redundant measurements of the same short or open circuit. Because the electrical load (45) creates an electrical connection between some of the phases in the controller (11) through the motor windings (44, 46, 48), a short circuit in one switch will affect voltage measurements in multiple phases. For example, if high side switch (81) in the first phase is shorted closed, current can flow from DC+ terminal (64) through the shorted switch (81), through motor winding (44), through motor windings (46) and/or (48), thereby affecting voltage measurements across switches in other phases as well. If only one or the other phase indicated an issue, this would be a sign of either a defective voltage sensor, a defective load (such as an open winding), or a disconnected phase (such as a connector or cable fault). While this is helpful for error proofing, because the electrical load (45) is creating a connection between some of the phases in the controller (11), it may be difficult to determine which specific high side or low side switch has the deficiency.

### Systematic Fault Identification Methodology

The systematic approach to switch testing disclosed herein may enable precise fault identification through a methodical process of sequential switch activation and voltage measurement correlation to isolate faults to specific semiconductor switches, specific motor windings, or specific interconnections, thereby providing actionable diagnostic information for repair or replacement decisions.

The fault identification methodology may be based on the principle that each type of fault produces a unique ‘voltage signature’ across the array of voltage sensors (33, 34, 133, 134, 233, 234). By commanding specific combinations of switches to on and off states and observing the resulting pattern of voltage measurements across all phases, the data processor (10) can discriminate between different fault types and localize the fault to a specific component. This approach leverages the known electrical topology of the system—specifically, the series connection of high-side and low-side switches in each phase, and the Wye or Delta connection of electrical load between phases—to create a system of electrical constraints that must be satisfied for proper operation.

“For example, consider a three-phase controller as shown in FIG. 2. When all six switches are commanded to the off state, each of the six voltage sensors (33, 34, 133, 134, 233, 234) should measure approximately half the DC bus voltage (e.g., 200V in operational mode, or 20V in test mode). This represents the ‘normal signature’ or baseline condition, proving that the system is free of short circuit faults.

Due to the electrical coupling through the motor windings, a short circuit in Phase 1 will also affect voltage measurements in Phases 2 and 3, but in a predictable pattern. Specifically, if high-side switch (81) in Phase 1 is shorted, current can flow from DC+ through switch (81), through motor winding (44), through the common neutral point of the Wye connection, through motor windings (144) and (244). This current flow will cause the voltage across the switches in Phases 2 and 3 to be reduced as well. The specific pattern of voltage reductions across all six sensors can be used to identify if a short circuit or open circuit fault is present in the system, but it may not be possible to identify the exact location. For instance, if voltage sensors (33), (133), and (233) read voltages significantly lower than half the bus voltage, and sensors (34), (134), and (234) read voltages significantly higher than half the DC bus voltage, this signature definitively indicates a high-side short somewhere in the system, but it may not possible to indicate where the fault has occurred.

The data storage device (67) may store a comprehensive fault signature database that maps each possible fault condition to its expected voltage measurement pattern. This database may be implemented as a lookup table, decision tree, or pattern matching algorithm. In one embodiment, the fault signature database may include entries, such as:

Fault Type 1: High-side short in Phase 1

Expected signature when all switches are commanded open:
V₃₃<Vₜₕ₁
V₃₄>Vₜₕ₂
V₁₃₃<Vₜₕ₃
V₁₃₄>Vₜₕ₄
V₂₃₃<Vₜₕ₅
V₂₃₄>Vₜₕ₆

Where V₃₃ represents the voltage measured by sensor (33), Vₜₕ represents a threshold voltage, the ‘<’ symbol indicates ‘less than’, and the ‘>’ symbol indicates greater than. Likewise for each of the other sensors.

Fault Type 2: Low-side short in Phase 2

Expected signature when all switches are commanded open:
V₃₃>Vₜₕ₁
V₃₄<Vₜₕ₂
V₁₃₃>Vₜₕ₃
V₁₃₄<Vₜₕ₄
V₂₃₃>Vₜₕ₅
V₂₃₄<Vₜₕ₆
   Fault Type 3: Open circuit in motor winding (44)

Expected signature when all switches are commanded open:
Vₜₕ₇<All measured voltages<Vₜₕ₈
Signifying no short circuits present in the system.

Expected signature when high-side switch (81) is commanded on:
V₃₃<Vₜₕ₁
V₃₄>Vₜₕ₂
Vₜₕ₇<(V₁₃₃, V₁₃₄, V₂₃₃, V₂₃₄)<Vₜₕ₈

The fault signature database enables rapid, automated fault diagnosis. When voltage measurements are acquired, the data processor (10) may compare the measured pattern to the stored signatures and identifies the best match, accounting for measurement tolerances and noise. This pattern-matching approach is more robust than simple threshold comparisons because it uses information from multiple sensors in correlation, reducing false positive rates and improving diagnostic confidence.

### Fault Localization Through Load Disconnection

FIG. 4 is a flowchart of a method of operating a controller to control an electrical load to perform switch testing according to another example embodiment.

Referring to FIG. 4, the method of FIG. 4 is similar to the method of FIG. 3, except the method of FIG. 4 further includes additional steps. Like steps or procedures are indicated by like reference numbers in FIG. 3 and FIG. 4, and, as such, operation S300, S301, S302 and S304 may be the same as the operations discussed above with reference to FIG. 3, and repeated description will be omitted for the sake of brevity.

In operation S306, the data processor (10) or the driver (12) may disconnect the load from the controller (11) to isolate the faulted phase(s). The data processor (10) or the driver (12) may provide digital signals to the load isolation stage (13) to disconnect the electrical load (45) from any phases indicating a “short circuit” or “open circuit” fault in operation S304. Load disconnection may be accomplished by various means, including but not limited to opening isolation contactors or relays between the controller output terminals (24, 124, 224) and the load terminals; commanding all switches in the load isolation stage (13) for the faulted phase to an off state and maintaining them off; or activating a hardware disconnection circuit. After disconnection, additional voltage measurements may be taken across the switches with the load removed from the circuit. With the load disconnected, voltage measurements become more definitive because the electrical coupling between phases through the load windings is eliminated. Accordingly, the controller (11) may identify the specific semiconductor switch(es) or electrical load phases that are faulted.

### Fault Localization Without Load Disconnection

FIG. 5 is a flowchart of a method of operating a controller to control an electrical load to perform switch testing according to another example embodiment.

Referring to FIG. 5, the method of FIG. 5 is similar to the method of FIG. 4, except the method of FIG. 5 further includes additional steps. Like steps or procedures are indicated by like reference numbers in FIGS. 3-5, as such, operation S300, S301, S302, and S304 may be the same as the operations discussed above with reference to FIGS. 3 and 4, and repeated description will be omitted for the sake of brevity. Operation S306 may be omitted from the method of FIG. 5, or may be included as an optional step.

The method of FIG. 5 is similar to the above discussed methods, except the controller (11) may determine the exact placement of a fault based on whether or not the DC bus voltage is reduced or current flows through the phase when a short circuit between DC+ and DC− is intentionally created. For example, while the load remains connected, switches are commanded on and off in a specific order, and the state of the phase current and the DC bus voltage are monitored to ensure the intended result (DC bus voltage is reduced and/or current flows, or DC bus voltage is not reduced and/or current does not flow) at each step of the test process.

In operation S308, the data processor (10) or driver (12) may disable any high current/energy source (internal or external). For example, if the external voltage source (40) is capable of providing high current that could cause damage during testing, the data processor (10) may delay the test until the external voltage source (40) is removed or deactivated, command the external voltage source (40) to a current-limited mode, or may insert a current-limiting impedance in the circuit. Alternatively, the dual voltage supply (29) may transition to a test mode with inherently limited current capability.

In operation S310, the data processor (10) or driver (12) may perform short circuit detection. For example, the data processor (10) or driver (12) may command a particular switch of one of the phases off and command on the related switch (e.g., opposite switch in the same phase as the particular switch that was commanded off, such as turning on the high side switch (81) while the low side switch (82) is off) for the certain phase. With only one switch in a phase turned on, and the load connected, current should not flow because there is no complete circuit path (the other switch in the same phase is off, and the load provides a return path but not a direct short to the DC bus).

In order to determine whether current is flowing, the controller 11 may include current sensors (not shown) positioned to measure current in at least N−1 phases of the controller, where N is the total number of phases. The current sensors may comprise Hall effect sensors, current transformers, shunt resistors with differential voltage measurement, or other current measurement devices capable of detecting current flow during the diagnostic tests. The current sensors provide feedback to the data processor (10) indicating whether current is flowing through any of the controller phases when switches are activated during the test sequence. This current measurement capability complements the voltage-based diagnostic methods by indicating when short circuit test paths are intentionally or unintentionally created in the system.

In operation S312, the data processor (10) may detect whether or not a voltage level of the direct current bus (64, 66) is reduced by at least a threshold level when the related switch (e.g., high side switch (81)) is turned on. If the voltage level of the DC bus does collapse (e.g., decreases by at least the threshold level) when only one switch is turned on, this indicates a short circuit somewhere in the system that creates an unintended current path. The specific phase where the current flows can then be used to identify which component in the system has failed short.

In one illustrative example, operations S310 and S312 may be carried out as follows. At a certain time interval, the voltage sensor (32) measures or detects a voltage level prior to turning on the related switch while the dual voltage supply (29) is operating at lower test voltage level, and again measures or detects a voltage level during or after turning on the related switch while the dual voltage supply (29) is operating at the lower test voltage level. The data processor (10) may compare the measured voltage difference between the voltage levels. If the measured voltage difference is greater than or equal to the threshold level stored in the data storage device (67), the data processor (10), voltage sensor (32), one or more of these devices may determine that the voltage level has decreased by at least the threshold level, and indicate that a short circuit deficiency is present in the system. If the voltage level does not decrease by at least the threshold level, this indicates there is no short circuit in the system with which the particular switch can complete a conduction path between DC+ and DC−.

In operation S320, the data processor (10) may establish a fault indicator for the particular fault location based on the results of the test step(s). In some example embodiments, after determining that the deficiency is not present, the system may transition from providing the test voltage to providing the higher operational voltage and continuing with normal system operation.

As discussed above, in some example embodiments, the establishment of a fault indicator may include setting a flag to inhibit the vehicle from entering a ready-to-drive state and/or may include generating an alert for the operator or vehicle control system to the fault condition. In some example embodiments, the fault indicators may be stored in data storage device (67) along with associated diagnostic information such as which switches were being tested, measured voltage values, timestamp, and other relevant data.

Accordingly, the controller (11) may detect a short or open circuit fault in a particular semiconductor switch of the inverter or controller to inhibit (or, alternatively, prevent) damage to the electric load (15 or 45) connected to the inverter. For example, upon detection of a fault or short or open circuit in a semiconductor switch, the data processor (10) may disable operation of the controller at the higher operational voltage level to prevent damage to the controller or the electric load (45) coupled to the controller. For example, the data processor (10) may prevent the dual voltage supply (29) or external voltage source (40) from transitioning to operational voltage mode. Alternately, upon detection of the fault (short or open circuit) in a semiconductor switch or the electric load, the data processor 10 may switch off the dual power supply (29) or decouple the dual power supply (29) or direct current energy source from the DC bus, while generating an error code or a diagnostic code for transmission to a user interface, display, light, light-emitting diode, buzzer, audible alarm, or other indicator. In vehicle applications, the fault code may be communicated via an on-board diagnostics (OBD) system, a CAN bus message to a vehicle controller, or a wireless communication system to a fleet management or telematics system.

The diagnostic test mode may be initiated at various points in the system lifecycle and operation, providing flexibility in balancing diagnostic thoroughness against operational availability and user convenience.

In an example embodiment, diagnostic testing is performed in-house during manufacturing before the controller (11) is sold or deployed. This factory acceptance testing checks that all semiconductor switches, voltage sensors, and control circuitry are functioning correctly before the unit leaves the manufacturing facility. Factory testing may be performed using built-in test equipment (BITE) or external test fixtures that provide controlled power and monitor the diagnostic results. The controller (11) may store a factory test completion flag in non-volatile memory (data storage device 67) indicating that the unit has passed initial diagnostics, and may record the test results including measured voltage values for each switch. This factory test data provides a baseline for comparison with subsequent field tests, enabling detection of degradation over the product lifetime. Factory testing may be performed at both reduced test voltage and at full operational voltage to verify proper operation across the complete voltage range.

In another example embodiment, the controller (11) may be configured to perform diagnostic testing automatically when the controller (11) is powered up. This ‘test-before-operate’ approach provides maximum safety assurance by verifying system integrity before initiating an operational session. Upon application of power to the DC bus (64, 66), the data processor (10) automatically initiates the test sequence by: (1) maintaining the dual voltage supply (29) or external voltage source (40) at the reduced test voltage level; (2) executing the diagnostic tests described in FIGS. 3-5; (3) evaluating the test results against stored thresholds; and (4) only transitioning to operational voltage if all tests pass. If any fault is detected, the data processor (10) may inhibit transition to operational voltage and/or may generate an error code indicating the specific fault type and location. This power-up testing approach is particularly suitable for safety-critical applications such as electric vehicle propulsion, where ensuring system integrity before the vehicle begins moving is essential for occupant safety. The power-up test may be completed in a brief duration (e.g., 100 milliseconds to 2 seconds) such that the delay before the system becomes operational is minimally perceptible to the user.

In automotive applications, the controller (11) may integrate the power-up test with the vehicle's start-up sequence. For example, when the driver presses the start button or turns the key to the ‘ON’ position, the data processor (10) may initiate the diagnostic test while other vehicle systems (instrument cluster, infotainment, etc.) are also initializing. By the time the driver is ready to shift into gear and begin driving, the diagnostic test may be completed and the controller (11) ready for operation. If a fault is detected, the vehicle may display a warning message such as ‘Propulsion System Fault-Service Required’ and may prevent the vehicle from entering a ‘Ready to Drive’ state, so that the driver does not attempt to operate the vehicle with a defective motor controller.

In another example embodiment, the controller (11) may perform diagnostic testing at scheduled periodic intervals during operation or during scheduled maintenance intervals. For example, for systems that remain powered continuously or for extended periods (such as industrial motor drives or HVAC systems), power-up testing alone may be insufficient because faults can develop during operation. Periodic testing may enable detection of degradation or failures that occur between power cycles. The data processor (10) may be configured to initiate diagnostic tests: (a) after a predetermined number of operating hours (e.g., every 100 hours of operation); (b) after a predetermined number of thermal cycles, where a thermal cycle is defined as heating above a temperature threshold and cooling below a temperature threshold; (c) on a calendar schedule (e.g., once per week or once per month); or (d) after a set number of start-stop cycles. The scheduled test may be performed during a planned maintenance window when the system is not required for operation, or may be performed opportunistically when the system is idle.

The controller (11) may create a maintenance log of system health over time. By comparing test results from successive diagnostic cycles, trends in switch degradation or sensor drift can be identified before they lead to operational failures. The data storage device (67) may store a time-series of test results, including date/time stamps, measured voltages for each switch, and pass/fail status for each test. This data can be retrieved via a diagnostic interface (such as an OBD-II port in automotive applications, or a service tool connector in industrial applications) and analyzed to support predictive maintenance strategies.

In another example embodiment, the controller (11) may implement an intelligent or adaptive testing schedule that balances diagnostic thoroughness against operational convenience. This ‘smart mode’ testing adapts the testing frequency based on system usage patterns and operational context. For example, in electric vehicle applications where the vehicle may be turned off and on frequently (such as at stop lights or during short stops), performing a full diagnostic test at every power-up may be unnecessarily time-consuming and may reduce battery efficiency. The smart mode may also adapt the comprehensiveness of the diagnostic test based on context. For example, a ‘quick test’ mode may only execute the baseline test (FIG. 3) that detects shorted switches but skips the more time-consuming open-circuit tests (FIG. 5). The quick test may be completed in 50-100 milliseconds, minimizing delay for the user. A ‘comprehensive test’ mode executes all test sequences including open-circuit detection, fault localization, and correlation analysis, providing maximum diagnostic coverage but requiring 500-1000 milliseconds. The data processor (10) may select between quick and comprehensive testing based on factors such as time since last comprehensive test, presence of any previous fault indicators, or user/system preferences.

The flexibility in test scheduling enables the disclosed system to be adapted to a wide range of applications with different operational requirements and safety criticality. For safety-critical applications such as autonomous vehicle propulsion, comprehensive testing on every power-up may be utilized to provide reliability. For less critical applications, periodic testing may be sufficient. The data processor (10) may be configured with application-specific testing parameters stored in the data storage device (67), including: test frequency, test comprehensiveness, voltage thresholds, timeout values, and fault response actions. These parameters may be set during manufacturing based on the target application, or may be field-configurable by authorized personnel using a diagnostic tool, providing flexibility to optimize the balance between diagnostic coverage and operational convenience for each specific use case.

The diagnostic methods and systems disclosed herein provide a robust solution for detecting semiconductor switch deficiencies in controllers and/or open/short circuits in electrical loads, thus the system can identify both short circuit and open-circuit faults without risking damage to the controller, connected loads, or voltage supply systems. By identifying defective switches/loads and inhibiting subsequent operation when deficiencies are detected, the system may enhance safety, reduce potential damage to system components, and reduce costly field failures in applications such as electric vehicle propulsion systems. The voltage-based measurement approach provides significant advantages over current-only based fault detection methods. Because some of the disclosed methods rely only on voltage measurement, multiple power electronic components can simultaneously perform diagnostics without negatively impacting each other or causing DC link voltage fluctuations, thereby significantly reducing test time for systems with multiple converters. The absence of current flow during testing limits the risk of damage caused by the test itself and ensures no reduction of device life from repeated diagnostic cycles carried out over the component lifetime. The method can be executed with either reduced test voltage or full operational high voltage on the DC link, allowing the test to run without discharging the system—a critical advantage for battery electric vehicles where maintaining state of charge is essential. This voltage flexibility removes timing restrictions between when the test is performed and when the battery is connected to the system. Additionally, because the test operates at either voltage level, the functionality of the system can be verified periodically without completely shutting down the system, thereby improving diagnostic coverage for applications requiring functional safety. The ability to detect load disconnection, open circuits, or exposed high-voltage terminals before high voltage application prevents damage to components and identifies potentially hazardous conditions such as damaged cables or loose connectors that could pose safety risks.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm and functions described in connection with some example embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium (e.g., the memory 75).

According to some example embodiments, the memory may be a tangible, non-transitory computer-readable medium, such as a Random Access Memory (RAM), a flash memory, a Read Only Memory (ROM), an Electrically Programmable ROM (EPROM), an Electrically Erasable Programmable ROM (EEPROM), registers, a hard disk, a removable disk, a Compact Disk (CD) ROM, any combination thereof, or any other form of storage medium known in the art.

Some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particular manner, a function or operation specified in a specific block may be performed differently from the flow specified in a flowchart, flow diagram, etc. For example, functions or operations illustrated as being performed serially in two consecutive blocks may actually be performed concurrently, simultaneously, contemporaneously, or in some cases be performed in reverse order.

It will be understood that when an element is referred to as being “connected” or “coupled” to another element, it may be directly connected or coupled to the other element or intervening elements may be present. As used herein the term “and/or” includes any and all combinations of one or more of the associated listed items.

Although terms of “first” or “second” may be used to explain various components (or parameters, values, etc.), the components (or parameters, values, etc.) are not limited to the terms. These terms should be used only to distinguish one component from another component. For example, a “first” component may be referred to as a “second” component, or similarly, and the “second” component may be referred to as the “first” component. Expressions such as “at least one of” when preceding a list of elements, modify the entire list of elements and do not modify the individual elements of the list. For example, the expression, “at least one of a, b, and c,” should be understood as including only a, only b, only c, both a and b, both a and c, both b and c, all of a, b, and c, or any variations of the aforementioned examples.

Some example embodiments are described herein with reference to cross-sectional illustrations that are schematic illustrations of idealized examples. As such, variations from the shapes of the illustrations as a result, for example, of manufacturing techniques and/or tolerances, are to be expected. Thus, some example embodiments should not be construed as limited to the particular shapes of regions illustrated herein but are to include deviations in shapes that result, for example, from manufacturing.

The description of example embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. These modifications are intended to be included within the scope of the disclosure.

We claim:

1. A method of detecting whether a deficiency is present in a system, the method comprising:
providing electrical energy to semiconductor switches of a controller in the system;
measuring a direct current voltage across each of the semiconductor switches in the controller; and
detecting that the deficiency is present, if the direct current voltage measured across any of the semiconductor switches is higher or lower than a threshold voltage.

2. The method of claim 1, further comprising:
generating an alert in response to detecting the deficiency, wherein the alert comprises one or more of a visual display message, an illuminated indicator, or an audible alarm.

3. The method of claim 1, wherein the system includes an electrical load, the electrical load being one of an internal permanent magnet motor, a switch reluctance motor, a brake chopper resistor, or a filter network.

4. The method of claim 1, further comprising:
inhibiting a voltage supply from providing an operational voltage level to a direct current bus of the system, in response to detecting that the deficiency is present.

5. The method of claim 4, wherein the system is coupled to a propulsion motor operating as an electrical load, and wherein inhibiting providing of the operational voltage level inhibits the propulsion motor from driving a vehicle.

6. The method of claim 1, wherein the deficiency includes one or more of i) an open circuit of an activated semiconductor switch, ii) a short circuit of a deactivated one of the semiconductor switches, iii) a failure of a connection of the controller with an electrical load, or iv) a failure of the electrical load.

7. The method of claim 1, wherein the providing electrical energy comprises:
providing one or more test voltage levels to a direct current bus, the test voltage levels being equal to or less than a maximum level of an operational voltage level of the system; and
measuring the direct current voltage across each of the semiconductor switches while the test voltage levels are applied to the direct current bus.

8. The method of claim 7, wherein the method further comprises:
increasing the electrical energy supplied from the one or more test voltage levels to the operational voltage level, only after determining that there are no deficiencies present in the system; or that the deficiencies detected will not adversely affect functionality of the system.

9. The method of claim 1, further comprising:
generating a fault code identifying a location of the deficiency;
storing the fault code in a non-volatile memory; and
communicating the fault code to an external system via a data bus.

10. The method of claim 1, wherein measuring the direct current voltage comprises using voltage sensors having an input impedance such that the voltage sensors draw negligible current compared to a leakage current of the semiconductor switches.

11. The method of claim 1, further comprising:
detecting whether the deficiency is present on an adaptive testing schedule by selecting between a fast test mode and a comprehensive test mode based on one or more of: a time since last test, a presence of previous fault indicators, or system usage patterns, wherein in the fast test mode, the measuring measures the direct current voltage without disconnecting a load from the controller such that the deficiency is detected without identifying a location of the deficiency, and
in the comprehensive test mode, the method further includes disconnecting the load from the controller; and identifying the location of the deficiency in response to disconnection of the load.

12. The method of claim 1, wherein detecting whether the deficiency is present comprises:
comparing the direct current voltage across each of the semiconductor switches to a threshold voltage; and
identifying a short circuit deficiency, in response to the direct current voltage being less than the threshold voltage; and
identifying an open-circuit deficiency, in response to the direct current voltage being less than or greater than the threshold voltage,
wherein the threshold voltage for each semiconductor switch may be the same or different values.

13. The method of claim 1, wherein the measuring the direct current voltage comprises:
measuring the direct current voltage across each of the semiconductor switches, while each of the semiconductor switches are commanded off to identify whether a short circuit deficiency is present.

14. The method of claim 13, further comprising:
disconnecting a load from the controller; and
identifying a location of the short circuit deficiency in response to disconnection of the load.

15. The method of claim 14, wherein, the measuring the direct current voltage comprises:
after disconnecting the load from the controller, remeasuring the direct current voltage across each of the semiconductor switches, while each of the semiconductor switches are commanded off to identify the location of the short circuit deficiency.

16. The method of claim 1, wherein detecting whether the deficiency is present comprises:
measuring the direct current voltage across one or more of the semiconductor switches before a switch command for the one or more of the semiconductor switches is given;
measuring the direct current voltage across the one or more of the semiconductor switches after a switch command for the one or more of the semiconductor switches is given;
comparing the direct current voltage before the switch command to the direct current voltage after the switch command;
determining if a change in the direct current voltage after the switch command is greater than or equal to a threshold value; and
detecting that the deficiency is present if (i) the change in the direct current voltage is greater than or equal to the threshold value and the direct current voltage was not supposed to change by the threshold value, or (ii) the change in the direct current voltage is less than the threshold value and the direct current voltage was supposed to change by at least the threshold value,
wherein the threshold value for each semiconductor switch may be the same or different values.

17. The method of claim 1, wherein the detecting detects whether an open circuit deficiency is present by:
activating one of the semiconductor switches only after the detecting detects that no short circuit deficiencies are present in the system; and
measuring the direct current voltage across the activated switch and any of the semiconductor switches expected to be conductively connected to the activated switch.

18. The method of claim 17, wherein the activating includes sequentially activating each of the semiconductor switches; and
for each active switch, a same or a different subset of the semiconductor switches is monitored to determine if the open circuit deficiency exists.

19. The method of claim 13, wherein, in response to detecting the deficiency is present by measuring the direct current voltage, the detecting whether the deficiency is present further comprises:
identifying the short circuit deficiency by activating one semiconductor switch at a time and monitoring whether a direct current bus voltage collapses while operating at a test voltage; and
determining a location of the short circuit deficiency by measuring and evaluating which converter phases a discharge current passed through.

20. A controller of a system, the controller comprising:
a memory; and
processing circuitry configured to detect whether a deficiency is present in the system by,
providing electrical energy to semiconductor switches of the controller,
measuring a direct current voltage across each of the semiconductor switches in the controller, and
detecting that the deficiency is present, if the direct current voltage measured across any of the semiconductor switches is higher or lower than a threshold voltage.
